(19) United States
(12) Patent Application Publication
(10) Pub. No.: US 2002/0192850 A1
(43) Pub. Date: Dec. 19, 2002

(54) Laser diode graded index layer doping

(76) Inventors: Richard A. Stoltz, Plano, TX (US); Jeff A. Bullington, Orlando, FL (US)

Correspondence Address: SLATER & MATSIL, L.L.P., 17950 PRESTON RD, SUITE 1000, DALLAS, TX, 75252-5793, US

(21) Appl. No.: 10/147,276

(22) Filed: May 16, 2002

Related U.S. Application Data
(60) Provisional application No. 60/293,814, filed on May 25, 2001.
(60) Provisional application No. 60/293,903, filed on May 25, 2001.
(60) Provisional application No. 60/293,905, filed on May 25, 2001.
(60) Provisional application No. 60/293,907, filed on May 25, 2001.
(60) Provisional application No. 60/293,904, filed on May 25, 2001.
(60) Provisional application No. 60/293,906, filed on May 25, 2001.
(60) Provisional application No. 60/293,740, filed on May 25, 2001.
(60) Provisional application No. 60/315,160, filed on Aug. 27, 2001.
(60) Provisional application No. 60/344,941, filed on Dec. 21, 2001.
(60) Provisional application No. 60/344,972, filed on Dec. 21, 2001.
(60) Provisional application No. 60/356,895, filed on Feb. 14, 2002.

(51) Int. Cl. H01L 21/00

(52) U.S. Cl. 438/22

(57) ABSTRACT

These laser diode chips generate light parallel to the top surface and utilize gratings that diffract light out top and/or bottom surfaces. Thus they have both a long light generation region and a large output area, and can provide significantly higher power than prior art semiconductor-chip diodes. The chips utilize graded index (GRIN) layers to provide light containment in the core. Previously, such GRIN layers have not been doped. We have found that doping of a portion of the graded layers generally lowers resistance and increases efficiency of the semiconductor structure while retaining the light containment effectiveness of full-wavelength-height waveguide. Lowering resistance generally also lowers heat generation and thus increases reliability.

This application claims the priority benefit of the following U.S. Provisional Application Serial No. 60/293,814, entitled PARTIALLY-DOPED LASER DIODE GRIN, filed on May 25, 2001; Serial No. 60/293,903, entitled LONG CAVITY LASER DIODE, filed on May 25, 2001; Serial No. 60/293,905, entitled SLANTED FINGER LASER DIODE GRATING, filed on May 25, 2001; Serial No. 60/293,907, entitled NON-REFLECTIVE TOP LASER DIODE CONTACT, filed on May 25, 2001; Serial No. 60/293,904, entitled ETCH STOP FOR LASER DIODE, filed on May 25, 2001; Serial No. 60/293,906, entitled ION IMPLANTED LASER DIODE GRATING, filed on May 25, 2001; Serial No. 60/293,740, entitled TUNGSTEN CONTACT FOR LASER DIODE, filed on May 25, 2001; Serial No. 60/315,160, entitled ADVANCED GRATING-COUPLED LASER DIODE, filed on Aug. 27, 2001; Serial No. 60/344,941, entitled ADVANCED GRATING-COUPLED LASER DIODE, filed on Dec. 21, 2001; Serial No. 60/344,972, entitled COUPLED FIBER UNIT FOR GRATING-COUPLED LASER, filed on Dec. 21, 2001; and Serial No. 60/356,895, entitled LASER TO FIBER COUPLING TECHNIQUES, filed on Feb. 14, 2002; all of which applications are hereby incorporated herein by reference.

### CROSS-REFERENCE TO RELATED APPLICATIONS

This application is related to the following commonly assigned patent applications, all of which applications were filed on Mar. 22, 2002, and all of which applications are hereby incorporated herein by reference:

| Serial No. | Title |
|---|---|
| PCT/US02/08764 | Controlling Passive Facet Reflections |
| PCT/US02/08774 | Shaped Top Terminal |
| PCT/US02/09012 | Ion Implanted Grating |
| 10/104,574 | InGaP Etch Stop |
| 10/104,501 | Tungsten Diode Contact |
| 10/104,333 | Low Reflectivity Grating |
| 10/105,098 | Low Diode Feedback |
| PCT/US02/09087 | Laser-to-Fiber Coupling |
| 10/104,576 | Rapid Thermal Annealing of Waveguide |

This application is related to the following patent application which was filed on Mar. 22, 2002:

| Serial No. | Title |
|---|---|
| PCT/US02/09020 | Laser Diode with Output Fiber Feedback |

### TECHNICAL FIELD

These are improved devices and/or methods of making electrically-pumped chip-laser-diodes that are horizontal-light-generating but surface-emitting. The diodes are laser chips manufactured using semiconductor wafer processing techniques.

### BACKGROUND

A major source of interest has been to reduce the cost and complication of the assembly of electro-optic devices through the coupling of the light into an external waveguide or other media. The desire to effectively couple light has led to the development of vertically-emitting (surface-coupled) diodes (as opposed to edge-emitting diodes). The term “vertical” is used in the industry generally for any light output through the top and/or bottom surfaces, including, for example, light coming out at 45 degrees from the vertical. While these chips generate light horizontally (parallel to the top surface), they use gratings to change the direction of the light and couple light out top and/or bottom surfaces. The term “light” as used herein, includes not only visible light, but also infrared and ultraviolet. The term “laser” is used herein to describe light generating devices having an electrically or optically pumped active-region, including devices using two reflectors that form ends of an optical cavity and optical devices that accept a light waveform input and have an amplified light waveform as an output. Lasers generally amplify the light that is allowed to resonate in the cavity. The term “diode” is generally used herein to mean an electrically-pumped laser chip.

In addition to a horizontal-cavity edge-emitting type of laser, there are vertical-cavity, vertically-emitting laser chips, i.e., the vertical-cavity surface emitting laser, or VCSEL. VCSELs, however, have had substantially reduced performance and a complicated device structure that does not effectively translate across the different material systems (such as GaAs to InP) for low cost manufacturing. The gain volume for VCSEL is very small and thus the output power is low. Note that VCSELs, like edge-emitters, bring light directly out, without diffracting the light.

The need for better vertically-emitting structures has driven the industry to examine a wide number of methods to couple light vertically out of a horizontal cavity structure. Proposed structures include the use of gratings (see, e.g., U.S. Pat. No. 6,219,369 to Portnoi, et al. which uses a single diode on a chip, and U.S. Pat. No. 5,673,284 to Congdon, et al. which uses four stripe diodes on a chip). The classic approach to grating coupled devices is to utilize a surface blazed grating with fingers extending down into the surface of a cladding over the passive region to couple light from an active region (containing, e.g., a quantum well, a p-n homojunction or a double heterostructure) through the passive region, and then vertically out of the device. A typical such vertically-emitting laser might have an active region about 10 microns wide by 500 microns long, and two Bragg gratings as end-of-cavity-reflectors, and an output grating designed both to couple light out and to reflect light to the active region as the feedback (generally about 70-90% coupled out and 10-30% fed back to give the desired narrow-band emission).

### SUMMARY OF THE INVENTION

These chips generate light parallel to the top surface and utilize gratings that diffract light out top and/or bottom surfaces. Thus they have both a long light generation region and a large output area and can provide significantly higher power than prior art semiconductor-chip diodes.

The chips utilize graded index (GRIN) layers to provide light containment in the core. Previously, such GRIN layers have not been doped. We have found that doping of a portion of the graded layers generally lowers resistance and increases efficiency of the semiconductor structure while retaining the light containment effectiveness of full-wavelength-height waveguide.

We have found that the top GRIN layer generally is a major factor in the series resistance of laser diode chips. All chips we tested had at least about 40% of their series resistance in their top GRIN layer. With the high performance top metal-to-semiconductor contacts we tested, the percentages were over 60%. Lowering laser diode chip top GRIN resistance generally significantly increases efficiency and reliability.

Lowering resistance also generally lowers heat generation and thus increases reliability. While making less than full-wavelength-height waveguide GRIN layers might lower resistance, the lower height degrades light containment in the core and thus decreases efficiency. With our partially doped GRIN layers the efficiency gain generally is not compromised by degraded light containment.

Our wafer scale processing techniques produce chip-laser-diodes with a diffraction grating that redirects output light out the top and/or bottom surfaces. Noise reflections are carefully controlled, allowing significant reduction of the signal fed to the active region. This has allowed additional innovations. Combination gratings and additional gratings and/or integrated lenses on the top or bottom of the diode can also be made utilizing wafer scale processes, reducing or even eliminating the need for the expensive discrete optical elements traditionally required to couple light out (e.g., into an optical fiber) and reducing alignment problems (prior art packaging of a diode has required tedious manual positioning of discrete optics). The diffraction grating can redirect a novel feedback from the optical output (e.g., fiber) to produce lasing that aligns itself to the fiber input, and such self-aligned lasing further reduces assembly costs.

This can be an improved method of generating light within a III-V semiconductor structure and transmitting a substantial portion of the generated light out a surface of the semiconductor structure, the method comprising providing an n-doped semiconductor substrate; providing a core on the substrate consisting essentially of a lower GRIN layer, a light generating layer and an upper GRIN layer, the core having an active region and a passive region that is longitudinally-displaced from the active region, and the upper graded layer having an undoped lower portion and a p-doped upper portion; providing a semiconductor electrode layer over the upper graded layer; providing grating fingers over the passive region of the core; providing an upper metal contact on an upper surface on the semiconductor electrode layer over the active region and a lower metal contact on a lower surface under the active region; and applying a voltage between the upper and lower contacts, wherein light is generated in the active region and a substantial portion of the generated light is transferred out a top surface of the passive region. The doping of a portion of the graded layers generally lowers resistance and increases efficiency of the semiconductor structure while retaining the light containment effectiveness of a waveguide of full-wavelength-height.

In some embodiments, the p-doped portion of the upper graded layer is at least one-half as thick as the undoped portion of the upper graded layer. The p-doped portion of the upper graded layer may be at least as thick or at least twice as thick as the undoped portion of the upper graded layer. The n-doped portion of the lower graded layer may also be at least twice as thick as the undoped portion of the lower graded layer.

This can also be an improved method of fabricating a semiconductor laser diode, the method comprising providing an n-doped semiconductor substrate; providing a lower semiconductor graded layer on the substrate, the lower graded layer being at least partly undoped; providing a light generating region on the lower graded layer; and providing an upper semiconductor graded layer on the active-region-containing layer, the upper graded layer having a substantially undoped lower portion and a p-doped upper portion, the p-doped portion of the upper graded layer being at least one-half as thick as the substantially undoped portion of the upper graded layer.

This can also be an improved method of generating light within a core of III-V semiconductor structure and transmitting a substantial portion of the generated light out a surface of the semiconductor structure, the method comprising providing a core consisting essentially of a quantum well and upper and lower GRIN layers, the core being at least one wavelength high and containing doped and substantially undoped portions with the undoped portion of the core being less than one wavelength high.

The foregoing has outlined rather broadly the features and technical advantages of the present invention in order that the detailed description that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF DRAWINGS

For a more complete understanding of the present invention, and the advantages thereof, reference is now made to the following descriptions taken in conjunction with the accompanying drawing, in which:

FIG. 1 shows a view of a chip-diode laser with an external feedback mirror, which laser can be tuned by tilting the mirror;

FIG. 2 shows measured output intensity as a function of wavelength in nm from a chip-diode laser;

FIG. 3 shows a measured output intensity as a function of angle at which the beam diverges, both longitudinally (parallel to the top contact) and transversely (perpendicular to the top contact);

FIG. 4 shows a simplified longitudinal elevation cross-section of a structure with a tapered electrode that can be used with or without external components;

FIG. 5 shows a top view of a device with a shaped top terminal (metal contact and electrode) and a shaped grating that can provide both reflection control and beam shaping;

FIG. 6 shows a simplified elevation cross-section of a diode showing a grating shaping by varying the depth of grating fingers;

FIG. 7 shows an elevation cross-section with a top reflector and bottom-surface emission, and an ion-implanted grating;

FIG. 8 shows an elevation cross-section with a buried dielectric reflector and top-surface emission, and with the emission self-aligned into an optical fiber; and

FIG. 9 shows an elevation cross-section with a top reflector and bottom-surface emission, with a lower beam-shaping grating, and with the emission self-aligned into an optical fiber.

### DETAILED DESCRIPTION OF THE PREFERRED EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

This diode-chip-laser can provide narrow-band coherent light, (light that is virtually all in-phase and at, or essentially at, the same wavelength). These grating-coupled diode improvements generally enable, for the first time, combining of the functional advantages of non-semiconductor-chip (e.g., fluid) lasers with the efficiency, economy, and convenience of semiconductor-chip-manufacturing (wafer processing). These chips generate light parallel to the top surface and utilize gratings that diffract light out top and/or bottom surfaces. Thus they have both a long light generation region and a large output area, and can provide significantly higher power than prior art semiconductor-chip diodes.

The chips utilize graded index (GRIN) layers to provide light containment in the core. Previously, such GRIN layers have not been doped. We have found that doping of a portion of the graded layers generally lowers resistance and increases efficiency of the semiconductor structure while retaining the light containment effectiveness of full-wavelength-height waveguide.

Lowering resistance generally also lowers heat generation and thus increases reliability. While making less than full-wavelength-height waveguide GRIN layers might lower resistance, the lower height degrades light containment in the core and thus decreases efficiency. With our partially doped GRIN layers, the efficiency gain is not compromised by degraded light containment.

Our methods and devices make enhanced beam quality achievable in high-power solid-state diodes. Our structures generally substantially eliminate the more significant stray reflections in laser-diode chips. Surprisingly, this has allowed the signal (generally the feedback) to be greatly reduced (as opposed to prior art designs that have increased the feedback to get coherent light), while allowing significantly greater output power than prior art laser-diode chips. Our signal is preferably reduced to less than 4% of the output light for both internally fed-back and externally fed-back devices, as well as optical amplifier devices. The advantages of our designs generally include: more efficient coupling of light from the core into the output beam; more coherent output beam; narrower line-width output beam; and greater output power.

In external feedback embodiments, generally substantially all internal reflections back into the active region are essentially eliminated (including gratings with very-low reflectivity, preferably of less than 0.1% and more preferably less than 0.01% of the output light).

Further, unlike prior art gratings designed to reflect light to the active region, our gratings can be detuned to reduce not only certain stray, but also wanted (feedback) reflections from the gratings. In one type embodiment, internal feedback is provided by the output grating, but the feedback is reduced to less than 4% of the output power.

These techniques can use a combination of an out-coupling (diffracting) grating and feedback from the output optical fiber to produce directed lasing in which the output angle of light from the chip grating aligns itself to the fiber input. The self-directed lasing essentially provides a chip-fiber longitudinal alignment that greatly reduces costs, particularly when the fiber is a single-mode fiber with a core diameter of ten microns or less. A lens-grating (at least part of which can be combined with the out-coupling grating) can be used to allow higher output power. Beam-shaping by one or a combination of gratings can be used (some beam shaping can be done by a shaped top metal contact as well), e.g., to provide a Gaussian distribution for more efficient coupling into a single-mode fiber. Controlling of chip temperature can be used to control the output wavelength of the device. As noted, in some embodiments, the light distribution is also adjusted by non-linear patterning of the top contact and/or the grating entrance. One or more gratings integrated into the chip can be used to transfer a beam, preferably self-directed, from the chip directly into an optical fiber, eliminating expensive, non-integrated optics.

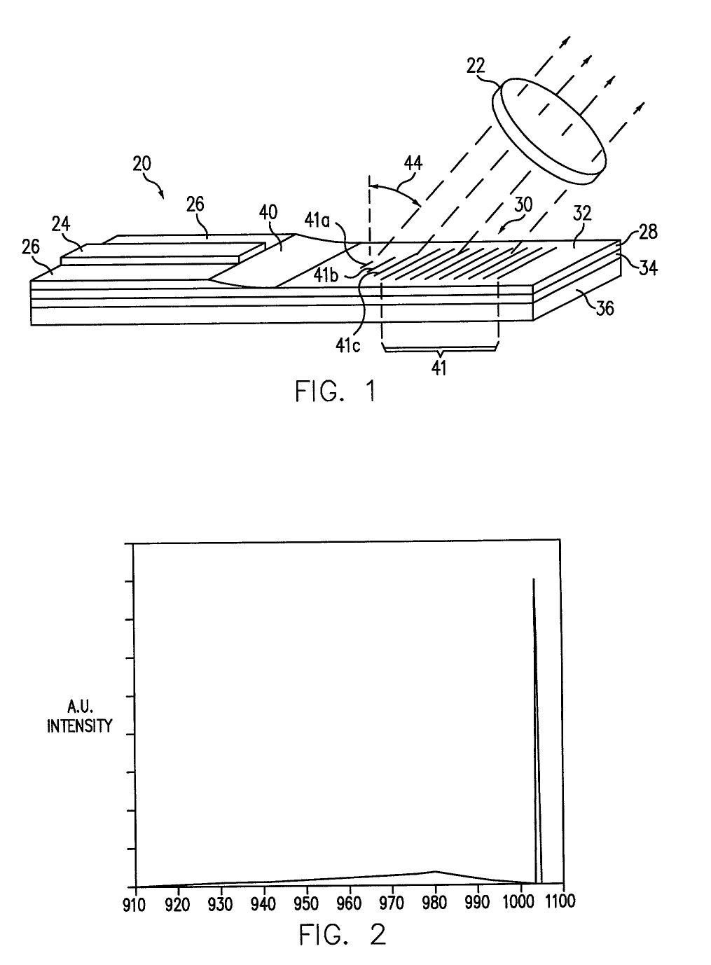

A view of a chip-laser diode 20 with external feedback is shown in FIG. 1. The external feedback reflector 22 shown is a partially reflecting mirror, however some preferred embodiments use other types of feedback reflectors. Output light is shown by dashed lines and has a generally cylindrical shape. The diode 22 has a top metal contact 24 on a top electrode 26. Top cladding layer 28 has a diffracting grating 30 (the diffraction grating can be a series of grooves etched in the top surface 32 of the top cladding layer 28). An active-region-containing core 34 is under the top cladding layer 28. The active-region-containing core 34 is over (possibly with intervening layers, not shown) a semiconductor substrate 36.

Generally layers are epitaxially grown on a semiconductor wafer for the active-region-containing core 34, the top cladding layer 28, and the top electrode 26; metal is deposited and patterned and etched for the top metal contact 24 and bottom metal contact; a patterned etch exposes top surface 32 of the top cladding layer 28 leaving an anti-reflection-shaped top electrode output end 40; and the diffracting grating 30 is patterned and etched as a series of grooves in the top cladding surface 32. The wafer is then cleaved into individual diode chips.

The substrate may be an n-plus InP wafer, 300 to 650 microns thick. The layer on top of the substrate is n-doped InP epi, 0.4 microns thick that provides a clean surface for further epitaxy and lower barrier. This is followed by a lower 0.3 microns thick, lattice matched layer, graded from InP to an end composition of InGaAsP of, in atom proportions, 0.71, 0.29, 0.66, and 0.34, respectively. The end composition of InGaAsP will be nearer the quantum well. This may be either undoped or undoped on the inside, e.g., the inside 0.03 microns, and n-doped on the outer portion. The quantum well is undoped InAsP, with a composition e.g., of InAsP, in atom proportions of, 1.0, 0.42, and 0.58, respectively, for a 1550 nm output. The next layer is an upper graded layer, from InGaAsP graded to InP, 0.3 microns thick, which may be undoped or undoped on the inside, e.g., the inside 0.03 microns nearer the quantum well, and p-doped on the outer portion. This is followed by a p-doped InAlAs 20 nm thick etch stop (composition of InAlAs of, in atom proportions, 0.52, 0.45, and 1.0, respectively) which will be used to provide an accurate penetration of grating fingers into the upper grating layer in later processing. This is followed by a p-doped InP epi, 0.4 microns thick which provides upper barrier, and a p-plus InP epi layer, 0.3 microns thick that will be the ohmic contact layer, for the upper metal contact. A similar approach of doping portions of the GRIN layers can be used on a wafer with an n-plus (e.g., 10¹⁸ doped) GaAs substrate.

The active region is generally the portion of the core 34 that is under the top metal contact 24. The waveguide region is generally a section of the core 34 that is under the diffracting grating 30 plus a connecting part of the core 34 between the active region and the section under the diffracting grating.

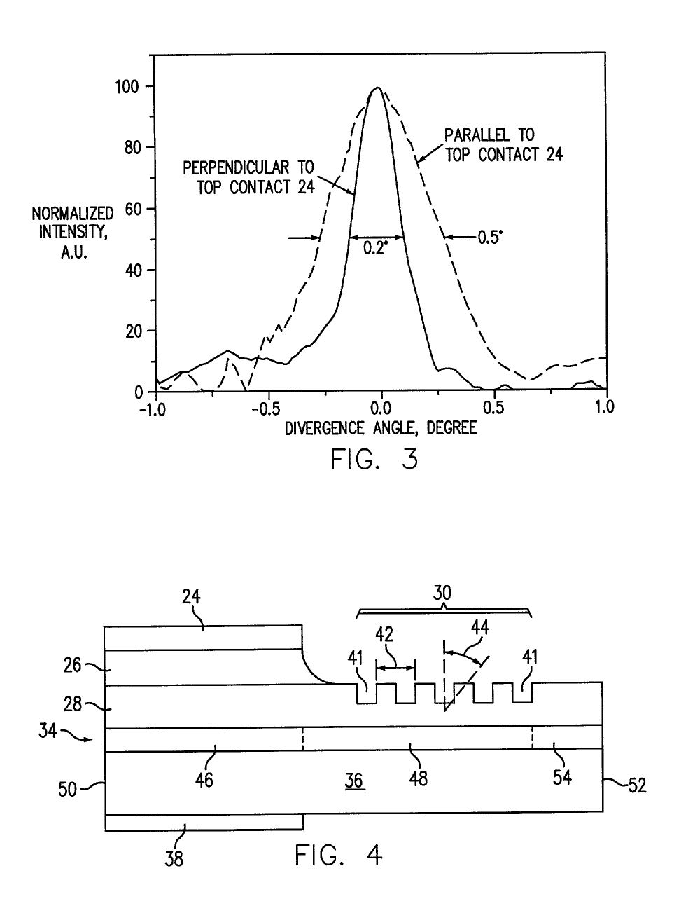

FIG. 2 shows light output as a function of wavelength, measured from one such diode. FIG. 3 shows light output as a function of wavelength, measured from one such diode.

FIG. 4 shows a simplified cross-sectional elevation about the longitudinal centerline of a diode chip (generally herein, like parts are designated by like numbers). Note that the drawings are generally not to scale. In this view, the bottom metal contact 38 can be seen on the bottom of the substrate 36. The diffracting grating 30 (shown greatly enlarged and with only a small fraction of the number of grooves) has a period 42 and an output beam at an angle 44 from vertical. The wavelength of the output light from a given quantum well structure is primarily a function of diffracting grating period 42, output beam angle 44, and chip temperature. The active region 46 is generally the portion of the core 34 under the top metal contact 24, and the waveguide region 48 of the core 34 is also indicated. The chip has an active-end facet 50 and a passive-end facet 52, which were formed during the cleaving operation. The active-end facet 50 can serve as one end of the laser-diode cavity, but the passive-end facet 52 in our embodiments is generally isolated such that there is substantially no reflection from the passive-end facet 52 back to the active region 46. In some embodiments, the passive core-portion 54 (adjacent the passive-end facet 52) is processed to be anti-reflective. Here the active-end facet 50 is a reflector that serves as one end of the laser cavity, with a mirror 22 that serves as the other.

In embodiments in which a device is to be an optical amplifier there are no cavity end reflectors, and a device is fabricated which is essentially two back-to-back devices of FIG. 4, (mirrored about the line of facet 50, but with no facet dividing the joined active regions, such that one grating can be used as an input, and the other as the output). Generally all the innovations herein incorporated can be used in fabricating and/or packaging optical amplifiers or even Superlume devices (which are broadband emitting devices which can use a FIG. 4 structure, but do not use a narrowband feedback).

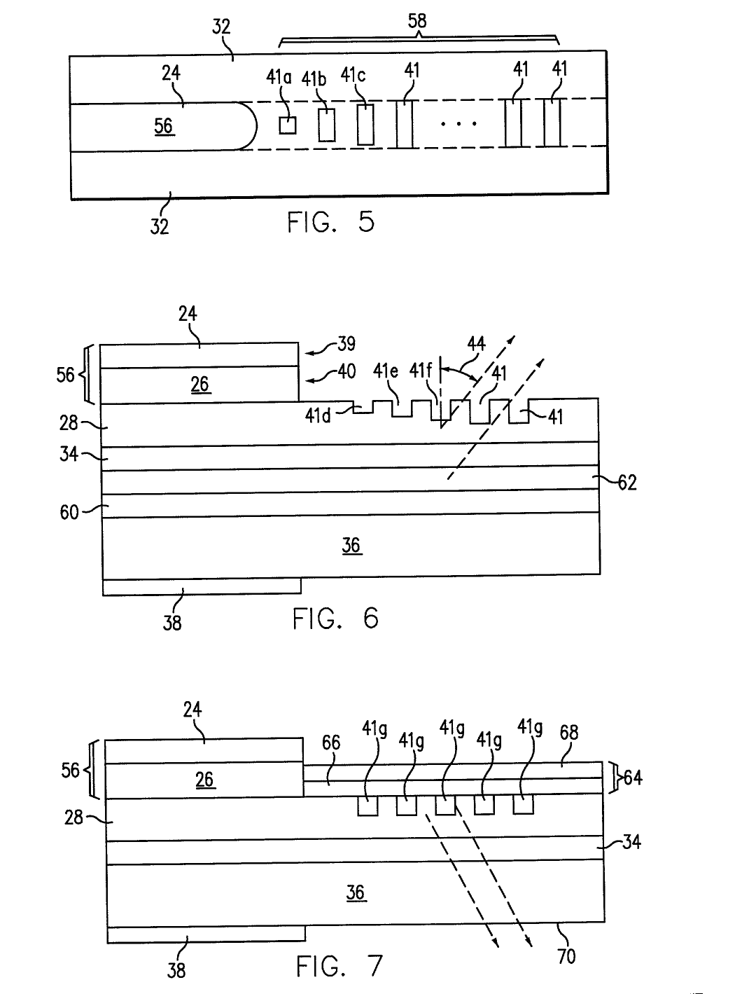

FIG. 5 shows a top view of a diode chip with a non-linear patterned top terminal 56 (non-linear patterned top terminal 56 can be formed by patterning and then etching both the metal contact layer and the top electrode layer) and a non-linear-patterned-entrance grating 58. Non-linear patterning can perform the functions of reflection-reduction and/or beam-shaping for either of, or both of, the top terminal 56 and the non-linear-entrance grating 58. The light intensity distribution in the output beam can be shaped, e.g., to give the beam a Gaussian distribution for more effective coupling into, e.g., a single-mode fiber. For example, making the top terminal “convex-shaped” on the end 56 towards the grating, and the grating “convex-shaped” on the end 58 towards the top electrode can make both the electrode and the grating ends essentially non-reflective and help shape the beam distribution. A finer sine-wave or other regular or irregular pattern can be superimposed on, or even to replace the smooth curve shown. With non-linear patterning, the top metal contact and the top electrode can both be dry etched (thus eliminating the less desirable wet processing) with a single patterning step. An anti-reflective coating on the top electrode end can also be used to reduce reflections into the active region. This version of the non-linear-entrance grating 58 uses grooves 41a, 41b, and 41c, that are shorter (fingers that are not as long) at the end nearer the active region than the other grooves 41 in the remainder of the grating (alternate versions use shallower grooves on this end).

Diffracting gratings can cause output light to be split into upward diffracted light beams and downward diffracted light beams, and efficiency can often be increased by combining these beams with some type of mirror (care generally needs to be taken to obtain a generally in-phase combination).

FIG. 6 shows a view similar to FIG. 4, but with a buried multi-layer dielectric mirror 60. The dielectric mirror 60 can have alternating layers (not shown) of materials with different dielectric constants, epitaxially grown during wafer epitaxy. The dielectric mirror 60 has a semiconductor spacer 62 (e.g., of the same material as the substrate) the dielectric mirror 60 is spaced to give in-phase combination of the beams (at the angle of beam travel by about one-quarter of the “in-material” wavelength below the grating 30 or three-quarters, one and one-quarter, etc., spacing). Note that FIG. 6 shows grooves 41d, 41e, and 41f, that are shallower (fingers with less depth) at the end nearer the active region than the grooves 41 in the remainder of the grating. Note also FIG. 6 shows the top metal contact 24 and the top electrode 26 with cross-sections produced by dry etch in forming top terminal 56 and also shows shaped output-end of top metal contact 39 and anti-reflection-shaped top-electrode output-end 40 shaped by dry etching. The top metal contact 39 is shaped primarily for beam shaping. When the contact 39 and electrode are etched with a single patterning, the top-electrode output-end 40 may need additional anti-reflection treatment, such as performing the patterning with a finer sine-wave or other regular or irregular pattern superimposed, and/or with an anti-reflective coating, as noted above.

FIG. 7 also shows a view similar to FIG. 4, but with a top mirror 64. The top mirror 64 is formed after the grating 30 is etched, and has a transparent (at operating wavelength) material 66, such as silicon dioxide, deposited in the grating grooves and over the top cladding surface and a metallization 68 deposited on the transparent material 64. The top mirror 64 is spaced to give in-phase combination of the beams (e.g., by about one-quarter of the in “transparent material” wavelength; a 990 nm in air wavelength would be 660 nm in glass with an index of refraction of 1.5, or 165 nm/cosine Theta) below the grating 30. With a top mirror, the output beam passes down through the substrate and out the bottom surface 70. As the transparent material 66 may have an index of refraction less that one-half that of the semiconductor, the transparent material 66 may be more than twice as thick as the spacer 62. Alternatively, FIG. 7 also shows fingers 41g that are ion-implanted regions. Ion implantation done with helium or argon can convert crystalline semiconductor material into amorphous material to provide grating fingers with bottom portions extending down into the cladding over the passive region of the core. Implantation can be patterned using photoresist.

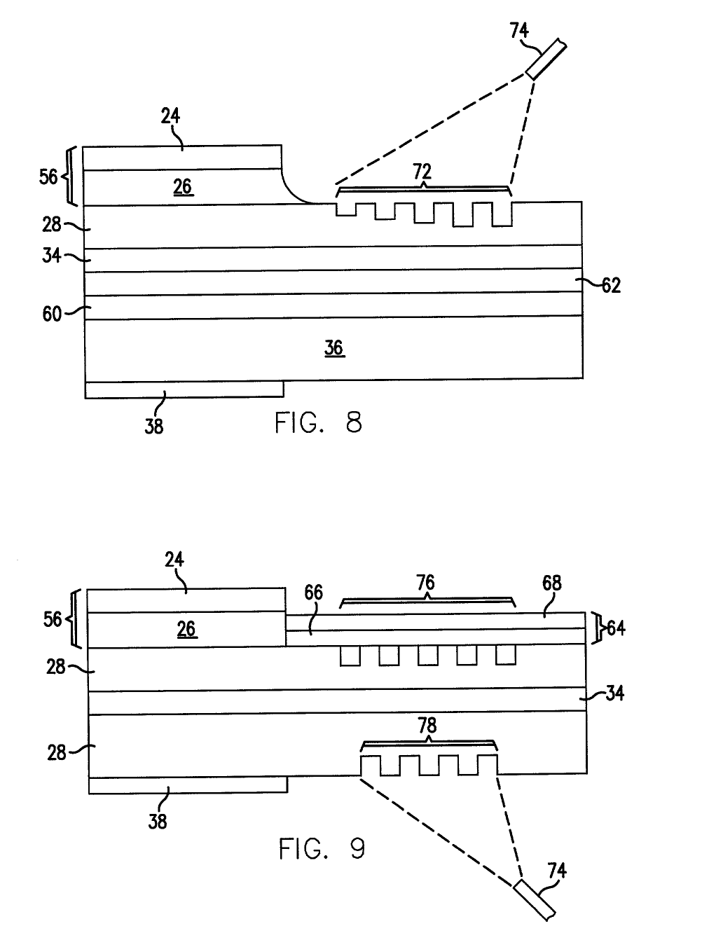

The diffracting grating 30 can be modified to be a combination grating that provides beam shaping as well as diffraction. FIG. 8 shows a view similar to FIG. 6, but with a combination grating 72 that diffracts and also focuses self-directed light into an optical fiber 74. The output light is self-directed due to a novel arrangement that uses reflected light from the fiber as feedback. The combination grating 72 could also be used in an arrangement similar to FIG. 7, with focused light going out the bottom surface. In some cases, a coupling block (which may have an internal grating) can be used between the chip (e.g., adjacent a glass-filled grating) and a fiber.

FIG. 9 shows a view similar to FIG. 7 (FIG. 9 also uses ion-implanted fingers), with a spaced-set of upper and lower gratings 76 and 78, where the use of a spaced-set allows more flexible beam shaping, e.g., diffraction (generally in the upper grating 76) and also Gaussian-distribution-adjusting and focusing in the combination of upper and lower gratings 76 and 78. The lower grating 78 is shown in the substrate bottom and unfilled (in some cases it can be glass-filled). The grating could also be in a silicon nitride or silicon dioxide layer on the substrate bottom. In single mode operation, the light rays are generally parallel to one another, when passing between the upper grating 76 and the lower grating 78. The rays can be perpendicular to the bottom surface, or on angle (e.g., 17 or 25 degrees from vertical).

The configuration of FIG. 9 is preferred especially for low power operation, where high power-densities at air interfaces are not a major problem. Preferably the fiber is spaced at least 5, and more preferably about 6, mm from the chip. With higher power diode chips, a glass coupling-block (not shown) can be inserted between (and optically glued to) the chip and the fiber. With a coupling-block, the fiber end and/or top of the block can be angled. The coupling-block can be a glass stub, preferably at least 3 mm long (e.g., of multi-mode fiber of about 100 micron diameter, preferably not graded-index, about 4 mm long). When a coupling block is used, there is preferably a controlled reflectivity joint between the coupling-block and the fiber.

Alternately (also not shown), one can have top grating that diffracts and an internal (e.g., focusing) grating within a two-part, glass coupling block. Both the top grating and the internal grating can aid in the shaping (e.g., Gaussian-distribution) of the beam (preferably all rays exiting the top grating are parallel and any focusing is provided by a grating spaced, e.g., by one-hundred wavelengths or more from the top grating). As used herein “spacing” in wavelengths is to mean wavelengths in the medium in which light is traveling, and thus the nominal output wavelength of the device corrected by dividing by the effective index of refraction of the medium. The use of a coupling block can eliminate all solid-to-air interfaces in coupling light between the chip and a fiber.

The core (lower and upper GRIN layers below and above the quantum well), may, e.g., in a single quantum well GaAs diode be 0.4 micron high (a little over one wavelength high for the wavelength in this medium) and contain a 6 nanometer quantum well between the lower and upper GRIN layers. Thus the core is the quantum well and the GRIN layers and is, to retain light-containment effectiveness, at least one wavelength high for the wavelength in this medium, e.g., 980 nm/(the index of refraction of GaAs). The substantially undoped portion of the core, however, is less than one wavelength high for the wavelength in this medium, to lower resistance and to increase efficiency of the semiconductor structure. The term “substantially undoped” as used herein includes doped to less than 10¹⁷. Doped means at least 2 times 10¹⁷. In some embodiments, either or both GRIN layers have portions doped to about twice background levels to provide controlled levels in substantially undoped portions. Zinc as the p-dopant is preferably avoided (using, e.g., beryllium instead) to lower diffusion when using thinner cores.

In preferred embodiments, the lower portion of the core is provided by a lower graded index layer and the upper portion of the core is provided by an upper graded index layer. In some top-emitting embodiments, the buried dielectric mirror is epitaxially grown beneath the core during wafer fabrication. The grating normally causes light to travel, not only out the top surface, but also down into the substrate, but the mirror directs all light out the top, increasing efficiency. The mirror is at a depth such that light going down into the substrate is reflected out the top surface, and is generally in-phase with the other light going out the top surface. The depth of the mirror is preferably a function of the angle (theta, from vertical) at which the light exits the surface (4 sine theta times the wavelength). If the light exit angle and the wavelength are adjustable, the depth can be set for the center of the adjustment range.

In some preferred embodiments, where the grating fingers are formed by changing portions of the crystalline semiconductor (with an index of refraction typically above 3) into an amorphous state (with an index of refraction typically about 1.5), the ion implantation is performed with, e.g., helium or argon. Preferably implantation angled at between 2 and 10 degrees from vertical is used to produce slanted fingers tilted between 2 and 10 degrees from vertical.

In GaAs substrate embodiments, prior art gratings have generally been in an AlGaAs layer. In a preferred GaAs embodiment, our diodes have an InGaP layer epitaxially grown over (preferably directly on the top of) the core (in particular over a GRIN layer which is the top of the core). This can provide an etch-stop-layer for accurate vertical location of the top of the grating, and, when a grating is etched into it, provides an aluminum-free grating (avoiding problems of aluminum oxidation), and also enables fabrication of saw-tooth gratings using anisotropic etching of InGaP.

In external cavity embodiments, the reflection from the grating into the active region is reduced, preferably to less than 0.1 percent of the intensity of the light entering the waveguide from the active region (and more preferably to less than 0.01%, and still more preferably to less than 0.001%). This can be done by at least one of the following: a combination of grating spacing and finger depth to reduce the zero-order and second-order of the grating to at least near minimum for the operating wavelengths; increasing the vertical distance between the grating and the core; and using a grating with saw-tooth or sinusoidal cross-section. In many such embodiments, the reflector is placed 5 or 6 mm from the diffraction grating and may be placed within an optical fiber.

By lowering reflections from the output grating, the passive-end facet, the electrode end nearest the grating, and the grating-end nearest the active region, a very low intensity feedback signal can be used. Typically Fabre-Perot diodes use a feedback of about 30 percent of the intensity of the light exiting from the active region. Output gratings of grating-coupled diodes are generally designed to “optimize” (increase) their reflectance, generally to 20% or 30%. Our technique uses less than 10% (and more preferably less than 4%, and still more preferably less than 1%). Prior art lasers typically have about 90% intensity at the facet near the electrode and are limited in power by intensity-related facet damage. Our diodes preferably have between 10% and 20% of active-region-output intensity at the electrode end facet (and far less at the passive-end facet).

While the passive-end-reflectors of our cavities are preferably facets (especially metallized facets), these techniques can also be used with Bragg gratings as the active-end-reflector.

Our grating can couple output light “vertically” out of a horizontal-active-region (e.g., quantum well) device. This minimizes loss and noise producing reflections back into the active region. Stray reflections may be eliminated, e.g., by dispersing or absorbing the light. This minimizing of the loss and noise producing reflections allows the desired feedback reflections to be reduced as well. Power output in a typical edge-emitting diode is generally limited by facet damage on the active-end facet, while our surface output area is much larger and allows much higher output. Power output in prior surface-emitting lasers has been limited by facet damage on the passive-end facet. Our lowering of the feedback lowers the power at this facet, and allows higher output power. While some diodes use Bragg gratings as reflectors in place of the active-end facet, these are more difficult to fabricate and less reflective than metallized facets, and thus such diodes are generally both more expensive and less effective than our devices.

Such a grating can also be constructed in a manner that allows the grating to interact with the electromagnetic radiation in the core of the diode, producing an embedded optical element (e.g., etalon and/or echelette) in a solid-state diode. The design of this intra-cavity optical element can allow the modification of the emission laser diode to produce, e.g., very-narrow-line-width light, similar to any of the modifications which have been done in fluid lasers (including partially gas, partially liquid, dye lasers), but never before integrated within the solid state device.

Generally, this is a horizontal cavity laser diode structure with top and/or bottom surface output. Electrically-pumped, diode structures can be made in a traditional manner on a wafer of the desired semiconductor material. A high spatial resolution grating can be exposed in photoresist onto the top surface of the structure over the passive region, but not over the active region, utilizing, e.g., an angled 5 degrees from vertical RIE etching. While the grating can be left unfilled, in some embodiments, grating is then filled, e.g., with an SiO₂ glass with an index of refraction ˜1.5, deposited, e.g., by CVD (e.g., PEMOCVD).

A tunable configuration of FIG. 1 was successfully used in experiments to prove the viability of the concept utilizing an external optical element. “Tunable,” as used herein, generally means changing the output wavelength other than by changing the temperature of (at least a portion of) the laser diode or by controlling a current passing through the laser diode. An essentially non-reflecting grating coupled light out (and back in from the mirror). Feedback and passive-end reflection was provided by a movable external, partially-reflecting mirror.

The core, e.g., in a single quantum well GaAs diode may be 0.4 micron high (a little over one wavelength high for the wavelength in this medium) and contain lower and upper GRIN layers below and above a 6 nanometer quantum-well. There also may be a lower semiconductor cladding layer about 1 micron high of e.g., AlGaAs below the core. The portion of the core directly below the upper electrode is the active region and the remainder of the core is sometimes described as a passive region. The passive region is longitudinally-displaced from the active region. The upper semiconductor cladding may be an AlGaAs layer, but is preferably InGaP, e.g., 0.3 micron thick. The top electrode 26 is preferably of highly doped semiconductor. The grating in upper semiconductor cladding has spaced fingers (there were actually hundreds of fingers in our experiments, but only about five are shown for drawing convenience). When a voltage is applied between the top and bottom electrodes, light is generated in the active region. The length grating is preferably at least one-and-a-half times as long (e.g., 600 microns) as the active region (e.g., 300 microns). The grating fingers 36 may have angled or tilted sides and bottoms to reduce the reflection from the grating back into the active region. A 2 to 10 degree tilt has been found to aid in reducing stray reflection from the grating.

Preferably, the electrode material is highly-doped semiconductor and has a metal contact on the outer surface. In one preferred embodiment, the metal directly on the highly-doped semiconductor is tungsten deposited by CVD (preferably using hydrogen reduction from tungsten hexafluoride). The CVD of tungsten is described in U.S. Pat. No. 3,798,060, “Methods for fabricating ceramic circuit boards with conductive through holes” by Reed and Stoltz which is incorporated herein by reference. The surface of the tungsten may then be coated with gold (also described in the above patent) or first nickel, then gold. Molybdenum-copper and tungsten-copper can also be used over the CVD tungsten. This tungsten metal contact system may be used as part of the top contact, the bottom contact, or both.

A grating design principle for a tunable configuration of FIG. 1 was based on the grating equation: d(n_{eff}−Sine Theta)=kλ, where k is diffracted order and is an integer, λ is the wavelength of the electromagnetic radiation, d is the grating period (see 42 of FIG. 4, the start of one finger to the start of the next), n_{eff} is the effective index of refraction of the grating (generally experimentally determined, but generally only slightly less than the semiconductor material of the cladding, e.g., here 3.29 as compared to the 3.32 of GaAs) and Theta (output beam angle from vertical, 44 of FIG. 1) is the angle of the feedback mirror. The bottoms of the fingers utilized may be slanted at 5 degrees from the horizontal. The slant is preferably at least 1 degree and is more preferably between 2 and 10 degrees (because of the angled etch, the walls were also slanted at about the same angle).

Etching channels for the fingers in the top cladding can create the grating. The fingers pass into the upper optical guiding cladding. The design of the grating takes into account the period, depth, aspect ratio, terminating shape, and index of refraction of the semiconductor material and grating filling material. In the internal fed-back devices, the frequency of the diode can be influenced by the angle of the termination plus other elements of the structure of the grating.

The structure controls reflection of optical noise (stray frequencies) into the active region of the laser diode. Three different sources of optical feedback (noise) due to reflections are: the reflection due to the termination of the top electrode, the reflection from the facet at the passive end of the core, and unwanted reflections from the output grating.

Controlling the shape of the top electrode at the termination can control the reflection due to the termination of the electrode (in the prior art it has been flat and perpendicular to the light in the core). The major contribution to this effect is at the end of the top electrode closest to the output region. The top electrode end closest to the output region may be shaped so that it is tapered with depth toward the passive region (see FIG. 4) by a wet etch. Conceptually, this can be like the termination of a microwave structure in a horn to control reflections. While the opposite end could be tapered in the opposite direction, this has not yet proved necessary. A non-flat shaping (in plan view, see FIG. 5) can be used and can be dry etched. These shapings can be used alternately or in combination.

The second noise is the reflection of light from facet 52 at the end of the passive region of the structure. The combination of the grating design and the length in the passive region can create a device structure that allows very little light to reach the facet 52 at the end of waveguide/passive region of our device. This dramatically reduces the optical noise that is reflected to the active region. This is in contrast to traditional edge-emitting diodes or Bragg grating de-coupled diodes that use this facet as one of the reflectors of the resonator cavity of the laser.

In the past, the reflection from the grating has been a maximized signal to be larger than the other sources of reflection. In our preferred structures, the other reflections are substantially eliminated and the grating reflection is reduced. This allows a low feedback reflection for internal cavity devices and substantially eliminates reflection for external cavity devices.

In one embodiment, a diode structure was designed to control the reflections to produce a diode with no external components and the feedback reflection was provided by the grating. The grating in this example is to be reflecting and thus the grating constant d may equal kλ/n_{eff}, such that the output light was essentially normal to the surface. Even though the grating is reflecting back into the active region, the reflection is reduced as described herein to less than about 4% of the power from the active region.

Even with a diffracting grating 30, unless appropriate measures are taken (e.g., greater grating 30 length, greater passive core-portion 54 length, absorbing of light via reverse biased electrode above and below the passive core-portion 54 or via ion-implantation of the passive core-portion 54, wet etch taper of the passive core-portion 54, and/or anti-reflective coating of passive-end facet 52), there is some reflection from the passive-end facet, and a higher feedback from the grating is required to avoid the above broadband emission. Our preferred core and grating can be about 100 microns wide.

Material in the quantum well layer in the waveguide region absorbs light at the output wavelength, and while some is reemitted, some inefficiency results. Efficiency can be improved by disordering this material. This can be done by implanting ions down through the top surface and into this area (while shielding the active region, e.g., with photoresist). As such ion implantation generally lowers the transparency of the waveguide, it is preferable to anneal the structure after ion implantation. The preferred procedure is rapid thermal anneal (RTA) by one or more short pulses of high intensity light from tungsten lamps (again while shielding the active region). While this disorders such parts of the quantum well layer, it can generally be done so as not to require an anneal after the treatment (the high intensity light is broad band, but the waveguide, other than the quantum well layer, is relatively transparent to the light and much more of the energy is absorbed in the quantum well, as compared to the rest of the waveguide). Such parts of the quantum well layer can also be disordered by “laser-induced-disordering” by energy from a laser tuned to the absorption wavelength of the quantum well, and, as the energy absorption in the device being treated is principally in the quantum well layer being disordered, a post-anneal is generally not required.

Optical filters can be used with RTA to substantially eliminate light of unwanted wavelengths (especially wavelengths which heat the non-quantum well parts of the waveguide). The RTA is effective, cheaper, and faster, and is generally preferred.

In some, especially tuned-diode, embodiments, this can be a method or laser diode that generates light within a III-V semiconductor structure at a wavelength of about 1550 nm and diffracts light out a top and/or bottom surface of the semiconductor structure, and includes using an InP semiconductor substrate; a horizontal core layer comprising an active region and a passive region; an upper cladding layer; and applying a voltage between top and bottom metal contacts, whereby light is generated in the active region and a substantial portion of the generated light is transferred out a top surface over the passive region. Generally, all layers except the quantum-well-containing layer are lattice matched. In some embodiments, an upper AlGaAS buffer layer is provided between the top cladding layer and the core, and a lower AlGaAS buffer layer is provided between the substrate and the core.

Generally the semiconductor laser diodes are of III-V compounds (composed of one or more elements from the third column of the periodic table and one or more elements from the fifth column of the periodic table, e.g., GsAs, AlGaAs, InP, InGaAs, or InGaAsP). Other materials, such as II-VI compounds, e.g., ZnSe, can also be used. Typically lasers are made up of layers of different III-V compounds (generally, the core layer has higher index of refraction than the cladding layers to generally confine the light to a core). Semiconductor lasers have been described, e.g., in Chapter 5 of a book entitled “Femtosecond Laser Pulses” (C. Rulliere—editor), published 1998, Springer-Verlag Berlin Heidelberg New York. The terms “patterning” or “patterned” as used herein generally mean using a mask (e.g., photoresist) to determine a pattern as in semiconductor type processing.

Traditionally, edge-emitting laser-diode chips optically coupled through lenses to output fibers have provided output light (“laser emission”) horizontally, with good energy efficiencies, reasonable yields, and the laser chip manufacturing efficiencies of wafer processing. Most edge-emitting laser diodes have a semi-reflecting (about 30% reflecting) passive-end (far end) facet which provides both the output of the edge-emitting laser diode and the feedback. Some edge-emitting lasers have used gratings as near-end (end nearer the active region) reflectors for the cavity and/or stabilizing (wavelength-narrowing) feedback, but not for output coupling. Their stabilizing feedback to the active region is generally about 30% of the light from the active region for the exit facet to give a narrow-band emission. In some other cases the stabilizing feedback has been from a fiber-optic pig-tail, external to an edge-emitting chip, e.g., with an A/R (anti-reflecting) coating on the exit facet. Although difficult to align with the output fibers (unlike grating-coupled devices, edge-emitting diodes do not couple effectively through a range of angles), these device designs have worked well for multiple wavelengths with a variety of materials such as GsAs, InP, and others.

The examples used herein are to be viewed as illustrations rather than restrictions, and the invention is intended to be limited only by the claims. For example, the invention applies to other semiconductor materials such as II-VI compounds. In some embodiments, an InP laser diode generates light within a III-V semiconductor structure at a wavelength of about 1550 nm out a surface of the semiconductor structure. Note also that the fingers of the grating can be silicon dioxide glass and thus can have an index of refraction the same as that of the optical fiber, or can be filled with air.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of generating light within a semiconductor structure and transmitting a substantial portion of the generated light out a surface of the semiconductor structure, said method comprising:
providing an n-doped semiconductor substrate;
providing a core on said substrate consisting essentially of a lower graded index layer, a light generating layer, and an upper graded index layer, said core having an active region and a passive region that is longitudinally-displaced from said active region, and said upper graded index layer having an undoped lower portion and a p-doped upper portion;
providing a semiconductor electrode layer over said upper graded index layer;
providing grating fingers over said passive region of said core;
providing an upper metal contact on an upper surface on said semiconductor electrode layer over said active region and a lower metal contact on a lower surface under said active region; and
applying a voltage between said upper and lower contacts, wherein light is generated in said active region and a substantial portion of the generated light is transferred out a top surface of the passive region.

2. The method of claim 1, wherein said semiconductor structure is a III-V semiconductor structure.

3. The method of claim 1, wherein said graded index layers are AlGaAs with said grading providing an increasing index of refraction towards said quantum well.

4. The method of claim 1, wherein said p-doped portion of said upper graded index layer is at least one-half as thick as said undoped portion of said upper graded index layer.

5. The method of claim 1, wherein said p-doped portion of said upper graded index layer is at least twice as thick as said undoped portion of said upper graded index layer.

6. The method of claim 1, wherein said lower graded index layer has an n-doped portion that is at least twice as thick as an undoped portion of said lower graded index layer.

7. The method of claim 1, wherein said p-doped upper portion of said upper graded index layer lowers resistance and increases efficiency of the semiconductor structure while retaining light containment effectiveness of a waveguide of full-wavelength-height.

8. A method of fabricating a semiconductor laser diode, said method comprising:
providing an n-doped semiconductor substrate;
providing a lower semiconductor graded layer on said substrate, said lower graded layer being at least partially undoped;
providing a light generating region on said lower graded layer; and
providing an upper semiconductor graded layer on said light generating region layer, said upper graded layer having a substantially undoped lower portion and a p-doped upper portion, said p-doped portion of said upper graded layer being at least one-half as thick as said substantially undoped portion of said upper graded layer.

9. The method of claim 8, wherein said p-doped portion of said upper graded layer is at least as thick as said substantially undoped portion of said upper graded layer.

10. The method of claim 8, wherein said p-doped portion of said upper graded layer is at least twice as thick as said substantially undoped portion of said upper graded layer.

11. The method of claim 8, wherein said p-doped portion of said upper graded layer is doped with beryllium.

12. A method of generating light within a core of a semiconductor structure and transmitting a substantial portion of the generated light out a surface of the semiconductor structure, comprising:
providing a core consisting essentially of a quantum well and upper and lower graded index (GRIN) layers, said core being at least one wavelength high and containing doped and substantially undoped portions, with said undoped portion of the core being less than one wavelength high; and
applying a voltage between said upper and lower GRIN layers.

13. The method of claim 12, wherein said semiconductor structure is a III-V semiconductor structure.

14. A chip-laser diode comprising:
an n-doped semiconductor substrate;
a lower graded index layer overlying said semiconductor substrate;
a quantum well layer overlying said lower graded index layer; and
an upper graded index layer overlying said quantum well layer, wherein at least one of said graded index layers is at least partially p-doped.
